(19) United States
(12) Patent Application Publication
(10) Pub. No.: US 2020/0326760 A1
(43) Pub. Date: Oct. 15, 2020

(54) CONTROL FAN USING NEURAL NETWORK

(71) Applicant: HEWLETT PACKARD ENTERPRISE DEVELOPMENT IP, Houston, TX (US)

(72) Inventor: Mark Barlow Hammer, Houston, TX (US)

(21) Appl. No.: 16/383,860

(22) Filed: Apr. 15, 2019

(51) Int. Cl. G06F 1/20; G06N 3/04; H05K 7/14

(52) U.S. Cl. CPC G06F 1/20; H05K 7/1487; G06N 3/04

(57) ABSTRACT

Examples disclosed herein relate to using a neural network to take inputs to control fans on a blade system. A chassis management controller is used to control the fans in the blade system. The blade system can have a number of blade slots. The chassis management controller can implement a neural network including multiple nodes. One of the nodes includes multiple inputs including a sensor input and a baseboard management controller input from one of the blades coupled to at least one blade slot. The neural network processes the inputs to determine an output. The output can be used to control a fan.

### BACKGROUND

Computing systems and many other electrical devices use components that can generate heat during operation. Many of these components need to be cooled to prevent damage to the component or other parts of the computing system or electronic device. One or more fans can be used to move air through the electronic systems and across heat generating components to transfer the heat to ambient air.

### BRIEF DESCRIPTION OF THE DRAWINGS

The following detailed description references the drawings, wherein:

FIG. 1 is a block diagram of a computing device including a chassis management controller that is capable of controlling a fan, according to an example;

FIG. 2 is a block diagram of a blade including a baseboard management controller and sensors, according to an example;

FIG. 3 is a flowchart of a method for controlling a fan based on a neural network output, according to an example;

FIG. 4 is a block diagram of a chassis management controller capable of controlling a fan based on a neural network output, according to an example;

FIG. 5 is a diagram of a neural network that can be used to control a fan, according to an example; and

FIG. 6 is a diagram of a node of a neural network that can be used to provide an output to be used to control a fan, according to one example.

Throughout the drawings, identical reference numbers may designate similar, but not necessarily identical, elements. An index number “N” appended to some of the reference numerals may be understood to merely denote plurality and may not necessarily represent the same quantity for each reference numeral having such an index number “N”. Additionally, use herein of a reference numeral without an index number, where such reference numeral is referred to elsewhere with an index number, may be a general reference to the corresponding plural elements, collectively or individually. In another example, an index number of “I,” “M,” etc. can be used in place of index number N.

### DETAILED DESCRIPTION

Thermal management of Information Technology (IT) and Operational Technology (OT) products is use to the overall health of a product. Many products include one or more fans and rely on one or more thermal sensor readings to decide what speed to run the fans at. In enclosures with a large number of sensors and a large number of fans, the complexity in determining the right speed to run each fan can become challenging to manage using the current standard approach: thermal tables. Accordingly, embodiments described herein employ a neural network of inputs to drive fan speed outputs. The neural network can adapt to a large number of sensors and a large number of fans without the need for large thermal tables.

Past solutions employ a table with simplistic algorithms to decide on fan speed settings. Such implementations can cross reference a thermal reading from a sensor or sensors to a cell in the table that will describe how fast to run each fan if this temperature is encountered. As you increase the number of fans and sensors, this table becomes many dimensional and challenging to create, comprehend, or maintain. This results in simplifying steps that take away fine-grained fan control and result in fans spinning at unnecessarily high speeds, wearing out the fans and wasting energy in the datacenter. Premature fan wear causes higher customer capital expenditures for replacements and wasting energy by spinning the fans too fast increases operational expenses. Fans that spin too fast also contribute to noise pollution which is a source of customer discontent.

At the other end of the spectrum are high performance compute solutions that use complex algorithms such as machine learning algorithms to monitor sensors of a cluster using a powerful processor running on a high level operating system. Information from many servers in a cluster can be used allow a central unit provide clusters. However this is a complicated system that can include additional latency to control cooling elements.

Accordingly, the current disclosure uses a neural network implemented at a chassis management controller of a blade computing system using the chassis as an enclosure for multiple blade devices. The approach scales well as the number of sensors and fan increases, enabling it to run the fans at the ideal speed to maintain temperatures. This prevents premature wear and wasted energy. Moreover, the approach is robust and can take into account location of sensors, temperature sensors, pressure sensors, humidity sensors, etc. as well as speed requests from particular devices, such as blades.

The network is defined by a series of nodes. Each node has one or more inputs. The inputs can be the outputs of other nodes, or values from outside the network such as sensor readings or other values. It could be temperatures, pressures, and speed requests from blades. The values can be customized and defined such that any value that a designer wishes to be taken in account for the fan control can be used.

In one example, in a node, each input is assigned a weight (e.g., a percentage weight). The weights can range from less than −100% to greater than 100%.

In one example, the inputs are combined in each node using a process to produce a single output for this stage. The combining algorithm can vary depending on system design sources. In one example, the maximum of the weighted inputs, the minimum of the inputs, the sum of the inputs, or any one of any number of combining algorithms can be used.

In one example, the combined output from a node's input layer is then run through a transfer function. Any one of any number of transfer functions may be used. Examples of transfer functions include a proportional-integral-derivative (PID) control algorithm and a running average. The parameters of each transfer function can be defined in a node description file of the node. In some examples, in addition to the transfer function, a maximum value and/or minimum value can be defined for a node. Offsets can also be applied.

In some examples, the manipulation within the node produces a single output for that node. In some examples, the nodal outputs can then, in turn, be fed into other nodes as inputs. The outputs of these nodes can be fed into still other nodes, and so on. Feedback loops can be created using this method, where the output of one node is fed back into either itself or a node upstream from it. Nodes can even be defined as having some inputs from other nodes and some inputs from raw sensor data. The resulting network can be as simple or as complex as needed to effectively manage the fans of a particular system. An advantage of this is a more precise handling fans speeds for audible levels, rotor wear levels, and power levels.

At some point, the outputs of one or more of these nodes can be used to define what a speed for a given fan, fan block, and/or fan zone will be. A chassis management controller takes these fan control values and feeds them to the appropriate fan, set of fans, zone of fans, fan block, etc. There can be any number of output nodes controlling any number of fans as needed for a particular system. Further, the fans can be split into zones and a location of sensors, blades, etc. within a zone can be used as part of a definition of a node. The output of that node can be used to control one or more fans within the zone.

With the approaches used herein, control algorithms can be created and tweaked quickly. This could speed up the release of a product including the neural network to control one or multiple fans in a system rather than a fan table. Moreover, because a chassis management controller included within a chassis of the computing device is used, the chassis manager can quickly change approaches.

By using neural networks in the approach described herein, special cases can be quickly dealt with. One example would be the case of some chassis components having multiple temperature sensors, and a developer only wishing to use the maximum temperature as the component's temperature value. With the thermal table method, a special case firmware algorithm would have to be written specifically for that component that would read all of its sensors and report only the maximum value. That would then be fed into the rigid fan table. With the neural network described herein, the multiple sensors of the component could be fed into a node whose output would be the maximum input. The output of that node could be used downstream in the network as the output of the entire component.

The approach also allows for flexibility in control. Individual fans can be controlled. Banks of fans can be controlled. Zones of fans can be controlled. Airflow in one zone can easily be taken in account for determining the airflow of an adjacent zone. This allows fans to run at more appropriate speeds, reducing premature fan failure and wasted energy, and resulting in quieter operation. Adjusting inputs per what other inputs are doing can easily be defined and controlled using the approach described herein.

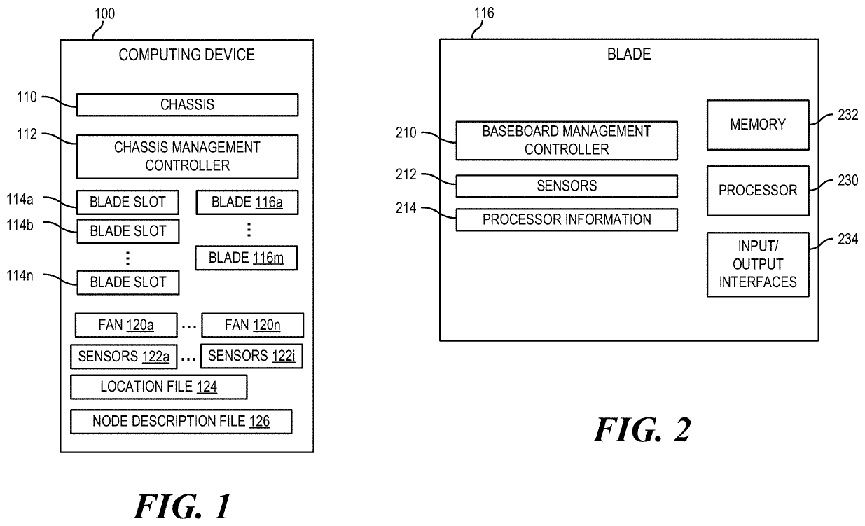

FIG. 1 is a block diagram of a computing device including a chassis management controller that is capable of controlling a fan, according to an example. Computing device 100 includes components that can be utilized to control fans using a neural network. The computing device may be a computer such as a blade server. The computing device 100 can include a chassis 110 with a chassis management controller (CMC) 112. The computing device 100 can also include a number of blade slots 114a, 114b-114n. One or more blades 116a-116m can be coupled to one or more blade slots 114. The computing device 100 can also have one or multiple fans 120a-120i. Similarly, the computing device 100 can include sensors 122a-122i. A location file 124 can be used to identify sensors for the neural network. Further, a node description file 126 can be used to create the nodes in the neural network, identify inputs and outputs for the grid, and properties of each node.

As used herein, a “blade” 116 may be a physical computing device that comprises memory and at least one logical processor, and that is mountable to a chassis or blade enclosure. In some examples, a blade 116 may be a modular computing device that is physically mountable to a blade or chassis for operation, that includes certain core computing resources (e.g., logical processor(s) and memory), and that excludes certain peripheral computing resource(s) (e.g., a power supply, cooling fan(s), external networking ports, and the like, or a combination thereof).

As used herein, a “blade enclosure” may be a chassis 110 to receive a plurality of blade devices and provide at least one peripheral resource for the received blade devices. For example, a blade enclosure may include fan(s) 120 to cool mounted blade devices, at least one power supply to provide power to mounted blade devices, external network ports for mounted blade devices, and the like, or a combination thereof. A chassis 110 is a frame or other supporting structure on which circuit boards or other electronics can be mounted.

In one example, a blade 116 may be a compute blade configured to provide processing and memory. In another example, the blade 116 can be a memory blade used as an expansion to provide additional memory to other blades 116. In some examples, the blade 116 can be an appliance to perform a special purpose. For example, the blade 116 may be an input/output or networking blade with multiple ports available. Different configurations of blades can lead to different nodes in a neural network being used and implemented.

A chassis management controller 112 is disposed on the chassis 110 (e.g., a blade enclosure). The CMC 112 is separate from a blade 116. Further, circuitry can be implemented to connect a communication interface between the CMC 112 to one or more of the blades 116 via blade slots 114.

In some examples, the CMC 112 can be used to implement services for the computing device 100. CMC 112 can be implemented using a separate processor from the processing element that is used to execute a high level operating system within the blades and a baseboard management controller supported in each blade. CMC 112 can provide so-called “lights-out” functionality for the computing device 100. The lights out functionality may allow a user, such as a systems administrator, to perform management operations on the computing device 100 even if an operating system is not installed or not functional on the computing device 100. Moreover, in one example, the CMC 112 can run on auxiliary power, thus the computing device 100 need not be powered on to an on state where control of the computing device 100 is handed over to an operating system after boot. As examples, the CMC 112 may provide so-called “out-of-band” services, such as remote console access, remote reboot and power management functionality, monitoring health of the system, access to system logs, and the like for the chassis and/or each separate blade.

In some examples, sensors associated with the computing device can be connected directly or indirectly to the CMC 112 and can measure internal physical variables such as humidity, temperature, pressure, power supply voltage, communications parameters, fan speeds, operating system functions, or the like. The CMC 112 may also be capable to reboot or power cycle the one or more of the blades 116. As noted, the CMC 112 allows for remote management of the device, as such, notifications can be made to a centralized station using the CMC 112 and passwords or other user entry can be implemented via the CMC 112.

In some examples, the CMC 112 can connect to a management platform that is external to the computing device 100 via a management network. Moreover, in some examples, the CMC 112 can be used to control the fans 120 and be coupled to sensors 122 and blades 116 via blade slots 114. In some examples, one blade may use multiple blade slots. In other examples, one blade 116 may use a single blade slot 114. As used herein, a blade slot 114 is a portion of an enclosure that has electrical components to attach electronics disposed on the chassis 110 to a blade.

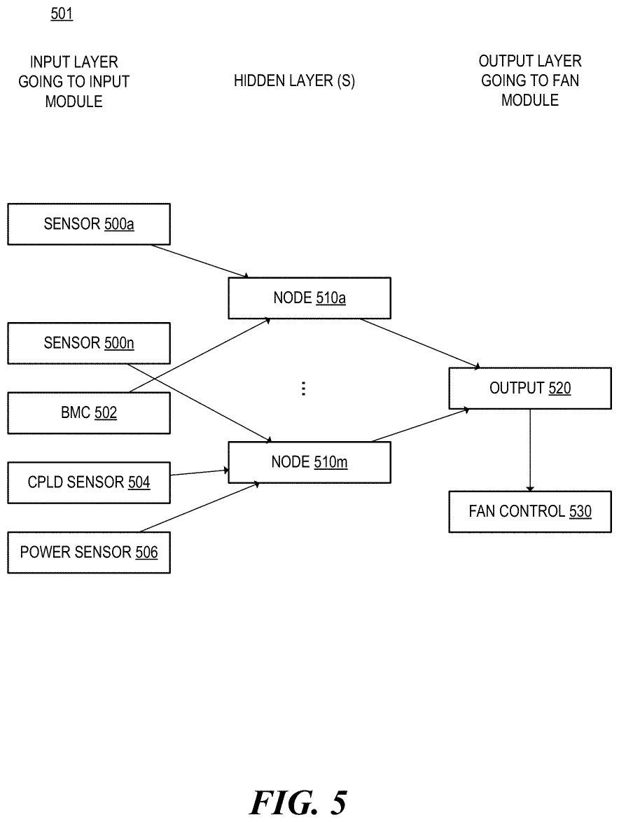

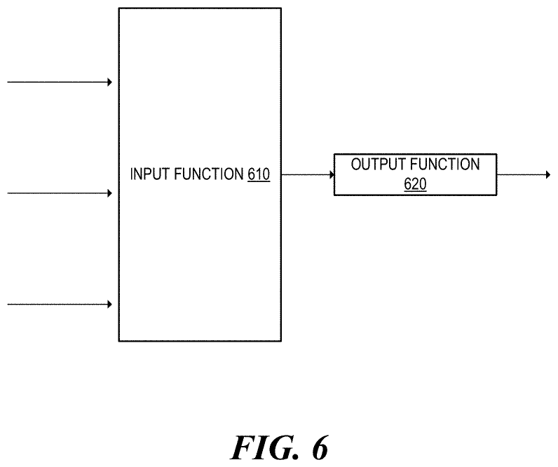

The CMC 112 can be used to implement a neural network that includes multiple nodes. Examples of a neural network and a node are shown in FIGS. 5 and 6. A neural network is an information processing paradigm that includes a number of interconnected processing elements working in unison to solve a specific problem. In this example, the problem can be considered to choose a fan speed for a fan or set of fans. The neural network includes nodes. The nodes can have inputs. The inputs can come from sensors 122, other devices, such as a baseboard management controller 210 from a blade 116, etc.

In one example, one of the nodes includes multiple inputs. The inputs in this example include an input that includes a sensor input and an input from a baseboard management controller (BMC) 210 of a blade 116 coupled to one of the blade slots 114.

The CMC 112 can know where the inputs are based on a location file 124. The location file 124 define a location for the CMC 112 to be able to contact each sensor/input and how to interact with that sensor/input to receive information. Examples of sensors 122 include stand-alone chassis sensors, sensors on various components such as a complex programmable logic device (CPLD) sensor, power supply sensors, sensors at various blades 116 in the system, etc.

In one example, a first blade 116 includes potential inputs (e.g., sensors, BMC, etc.). In another example, a second blade 116 can include other potential inputs.

As noted above, the sensors 122 and other inputs can be defined in a location file 124. The location file 124 can include information needed to access the sensors (e.g., temperature, pressure, current, power, voltage, etc. sensors). In some examples, the location file can be implemented as a human-readable text to transmit object information, for example as a JAVASCRIPT Object Notation (JSON) file, a text file, etc. In some examples, the location file can be considered a sensor description record (SDR).

In one example, the location file can include a part number, a number identifier, a type field, and an address field. The part number can identify a part uniquely (e.g., serial number). The type field can associate a particular sensor or sensor type or other input with a type. The type can be associated with criteria for that type, for example, a weight for a raw number output by that type. The number identifier can be used to identify which number the input is. This can be used to distinguish between different sensors on a table. Moreover, the address field can be used to indicate how the chassis management controller 112 can communicate (e.g., poll) with the input.

A node description file 126 can be used to describe the nodes of the neural network and the interconnections. The node description file can also be a human-readable text file. In some examples, the grid can be defined node by node. Nodes can be defined by their inputs, their weights for their inputs, various operations performed on data, etc. The nodes can also support optional debug reports to help facilitate grid development.

For each node, a specified weighting to each input can be applied. The weighting can be any percentage number from 0 through +∞ and even negative numbers. A weighting of 100 is 100% in this example.

In one example, thermal properties (e.g., temperatures) are received through sensors 122 for the node. These sensors 122 may have something in common, for example, a location associated with a cooling zone. In one example, a weighting can be used to ensure that each temperature sensor reading is at a same level as the others (e.g., a numeric value would represent the same thing). A function can be run on the weighted inputs. One example could be an average function such as a mean, median function. Another example function is a minimum function. Another example could be a max function, which could be of interest because this could be an area in need of cooling.

Another node can take into account pressure for the zone. The node description file 126 can specify how nodes are connected with each other. In some examples, a weighting can be performed on pressure sensor inputs. The weighted inputs can then be processed in the node. In this example, a minimum function can be beneficial to help determine an area with a lower amount of air flowing through in a particular area or zone.

Another node can take the temperature output and pressure output for the zone and process them together to determine a fan rate for a fan or set of fans. The thermal function can take other things into account, such as thermal properties of a blade, components, heat sinks, etc.

In another example, the fan rate from a node can be used as an input to another node. This other node may also have a fan speed request from a BMC as an input. In one example, the BMC may ask for a pulse width modulation (PWM) value for a fan as part of the input used. In some examples, the fan speed request may be weighted and combined with fan speed requests from other BMCs and/or a weighted fan speed output from another node. In one example, a function can be performed on the fan speed inputs to determine an output to a particular fan, a zone of fans, etc. The function can be a max function, where the speed for the fan(s) may be higher than what is requested by a BMC because of other considerations (e.g., from other nodes).

In some examples, the location file 124 and/or node description file 126 can be updated. In one example, the file is updated to support additional sensor inputs. A node description file 126 may add additional nodes, refine nodes, etc. A location file 124 can add additional potential inputs and their possible locations.

The files can be updated on the computing device 100 by interacting with the CMC 112. In one example, the CMC 112 can expose a network interface and a web server to allow a user or other entity (e.g., via an API) to interact with it. The CMC 112 can take update files. In some examples, the particular file can be updated while the computing device 100 is active. A process or function that uses the particular file can be restarted by the CMC 112 to enable usage of the updated file.

In some examples, a zone can be a portion of the computing device 100. The zone can be a particular volume or otherwise determined. In some examples, a set of fans or a zone of fans can be responsible for cooling that zone. The zone can include a number of sensors associated with that zone. In some examples, sensors in adjacent zones can be used as inputs to nodes. Further nodes with sensors in one zone may have an output to another node responsible for an adjacent or another node.

FIG. 2 is a block diagram of a blade including a baseboard management controller and sensors, according to an example. Blade 116 can include components that can be utilized to communicating sensor information to a CMC and to communicate information from a BMC 210. Sensor information can be gathered from various sensors 212 present on the blade 116. Processor information 214 may be conveyed by the BMC 210 as well.

In some examples, the BMC 210 can be implemented using an engine that includes hardware and/or combinations of hardware and programming to perform functions provided herein. Moreover, the modules (not shown) can include programing functions and/or combinations of programming functions to be executed by hardware as provided herein. When discussing the engines and modules, it is noted that functionality attributed to an engine can also be attributed to the corresponding module and vice versa. Moreover, functionality attributed to a particular module and/or engine may also be implemented using another module and/or engine.

A processor 230, such as a central processing unit (CPU) or a microprocessor suitable for retrieval and execution of instructions and/or electronic circuits can be configured to perform the functionality of any of executing a host operating system. In certain scenarios, instructions and/or other information such as virtual machines, production applications, etc. can be included in memory 232 or other memory. Input/output interfaces 234 may additionally be provided by the blade 116. In some examples, this can be via a communication fabric that can connect to ports on a blade enclosure. In one example, input devices, such as a keyboard, a sensor, a touch interface, a mouse, a microphone, etc. can be utilized to receive input from an environment surrounding the computing blade 116. Further, an output device, such as a display, can be utilized to present information to users. Examples of output devices include speakers, display devices, amplifiers, etc. Moreover, in certain examples, some components can be utilized to implement functionality of other components described herein. Input/output devices such as communication devices like network communication devices or wireless devices can also be considered devices capable of using the input/output interfaces 234.

In some examples, the BMC 210 can be used to implement services for the blade 116. BMC 210 can be implemented using a separate processor from the processing element or processor 230 that is used to execute a high level operating system. BMCs can provide so-called “lights-out” functionality for computing devices. The lights out functionality may allow a user, such as a systems administrator, to perform management operations on the blade 116 even if an operating system is not installed or not functional on the blade. Moreover, in one example, the BMC 210 can run on auxiliary power, thus the blade 116 need not be powered on to an on state where control of the blade 116 is handed over to an operating system after boot. As examples, the BMC 210 may provide so-called “out-of-band” services, such as remote console access, remote reboot and power management functionality, monitoring health of the system, access to system logs, and the like. As used herein, a BMC 210 has management capabilities for sub-systems the blade 116, and is separate from the processor 230 or processing element that executes a main operating system of a computing device (e.g., a server or set of servers).

As noted, in some instances, the BMC 210 may enable lights-out management of the blade 116, which provides remote management access (e.g., system console access) regardless of whether the computing device 200 is powered on, whether a primary network subsystem hardware is functioning, or whether an OS is operating or even installed. The BMC 210 may comprise an interface, such as a network interface, and/or serial interface that an administrator can use to remotely communicate with the BMC 210. As used herein, an “out-of-band” service is a service provided by the BMC 210 via a dedicated management channel (e.g., the network interface or serial interface) and is available whether the computing device 200 is in powered on state.

In some examples, a BMC 210 may be included as part of the electronics of the blade 116 and is separate from the CMC. In examples, the BMC 210 can be connected via an interface (e.g., a peripheral interface). In some examples, sensors associated with the BMC 210 can measure internal physical variables such as humidity, temperature, power supply voltage, communications parameters, fan speeds, operating system functions, or the like. The BMC 210 may also be capable to reboot or power cycle the device. As noted, the BMC 210 allows for remote management of the device, as such, notifications can be made to a centralized station using the BMC 210 and passwords or other user entry can be implemented via the BMC 210. In some examples, the BMC 210 can access health and/or metrics information 214 about the processor. This can include, for example, the speed the clock, the voltage usage, a temperature associated with the processor, knowledge of a function call that is expected to represent a large workload, etc.

A firmware engine can be implemented using instructions executable by a processor and/or logic. In some examples, the firmware engine can be implemented as platform firmware. Platform firmware may include an interface such as a basic input/output system (BIOS) or unified extensible firmware interface (UEFI) to allow it to be interfaced with. The platform firmware can be located at an address space where the processing element (e.g., CPU) for the blade 116 boots. In some examples, the platform firmware may be responsible for a power on self-test for the blade 116. In other examples, the platform firmware can be responsible for the boot process and what, if any, operating system to load onto the blade 116. Further, the platform firmware may be capable to initialize various components of the blade 116 such as peripherals, memory devices, memory controller settings, storage controller settings, bus speeds, video card information, etc. In some examples, platform firmware can also be capable to perform various low level functionality while the blade 116 executes. Moreover, in some examples, platform firmware may be capable to communicate with a higher level operating system executing on a CPU, for example via an advanced configuration and power interface (ACPI).

In certain examples, the BMC 210 can communicate with the CMC 112 via an interface such as a bus. The interface can be used to communicate sensor information from the blade to the CMC 112. In other examples, another interface can be used to allow the CMC 112 to directly poll one or multiple of the sensors 122 directly.

In some examples, the BMC 210 can execute health processes on the blade 116. During course of the management of the blade 116, the BMD 210 may wish to request a fan speed for the blade. One example time could be, for example, when the BMC 210 under goes an update, another example could be based on information processed with regard to temperature, pressure, humidity, etc. of a sensor. In another example, the BMC 210 can use sensor information (e.g., a particular sensor above or at a particular value) to request a fan speed. In these examples, the BMC 210 can send a request for a fan to be set to a speed. In some examples, the request can be via a PWM value. In some examples, PWM values can be used as inputs to fans to cause the fans to rotate.

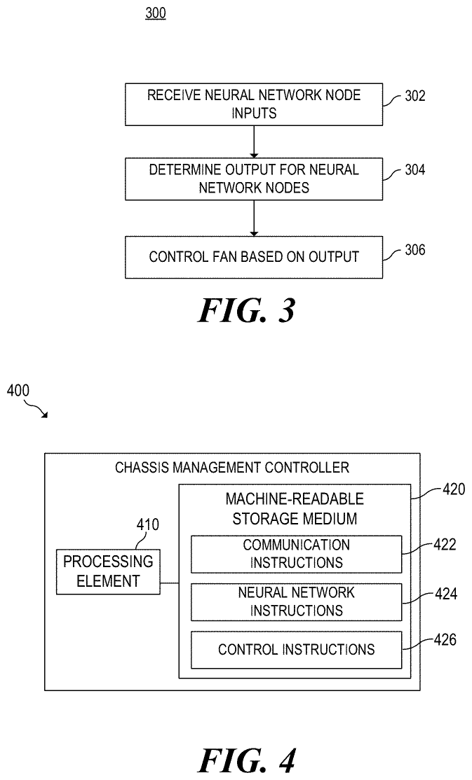

FIG. 3 is a flowchart of a method for controlling a fan based on a neural network output, according to an example. FIG. 4 is a block diagram of a chassis management controller capable of controlling a fan based on a neural network output, according to an example. CMC 400 may be implemented, for example, as an application specific integrated circuit (ASIC), a system on a chip, a combination of electronics, etc.

Processing element 410 may be, processing unit, one or multiple semiconductor-based microprocessor, one or multiple graphics processing unit (GPU), other hardware devices suitable for retrieval and execution of instructions stored in machine-readable storage medium 420, or combinations thereof. The processing element 410 can be a physical device. Moreover, in one example, the processing element 410 may include multiple cores on a chip. Processing element 410 may fetch, decode, and execute instructions 422, 424, 426 to implement method 300. As an alternative or in addition to retrieving and executing instructions, processing element 410 may include at least one integrated circuit (IC), other control logic, other electronic circuits, or combinations thereof that include a number of electronic components for performing the functionality of instructions 422, 424, 426.

Machine-readable storage medium 420 may be any electronic, magnetic, optical, or other physical storage device that contains or stores executable instructions. Thus, machine-readable storage medium may be, for example, Random Access Memory (RAM), an Electrically Erasable Programmable Read-Only Memory (EEPROM), a storage drive, a Compact Disc Read Only Memory (CD-ROM), and the like. As such, the machine-readable storage medium can be non-transitory. As described in detail herein, machine-readable storage medium 420 may be encoded with a series of executable instructions for performing method 300 and/or other approaches a CMC is described as performing described herein.

Although execution of method 300 is described below with reference to CMC 400, other suitable components for execution of method 300 can be utilized (e.g., CMC 112). Accordingly, in some examples, CMC 400 can be implemented as a CMC in computing device 100. Additionally, the components for executing the method 300 may be spread among multiple devices (e.g., ASICs and/or processors). Method 300 may be implemented in the form of executable instructions stored on a machine-readable storage medium, such as storage medium 420, and/or in the form of electronic circuitry.

At 302, the CMC 400 can receive, via execution of communication instructions 422 at a processing element 410, multiple neural network node inputs. These inputs can be raw sensor data and/or processed data, such a PWM fan speed request from a BMC. The reception can be in response to a polling for the information using one or more bus, selectors, switches, input/output interfaces, etc. As noted above, a location file can be used to determine the inputs, how to access the inputs, and settings for inputs.

Neural network instructions 424 can be executed to generate and then utilize a neural network. In some examples, a node definition file can be used to generate the neural network and then the nodes in the neural network can be used. As part of the usage, inputs for a node can be weighted as described herein. Further, at 304, the processing element 410 can determine an output for one of the nodes based on a neural network input from a sensor input as well as from an input from a BMC. In some examples, these can be direct inputs to the node. In other examples, one input can be processed at a first node and that output serving as an input (direct or indirect) for the node.

As noted, for each node, a specified weighting to each input can be applied. The weighting can be any percentage number from 0 through +∞ and even negative numbers. A weighting of 100 is 100% in this example.

In one example, thermal properties (e.g., temperatures) are received through sensors for the node. These sensors may have something in common, for example, a location associated with a cooling zone. In one example, a weighting can be used to ensure that each temperature sensor reading is at a same level as the others (e.g., a numeric value would represent the same thing). A function can be run on the weighted inputs. One example could be an average function such as a mean, median function. Another example function is a minimum function. Another example could be a max function, which could be of interest because this could be an area in need of cooling.

Another node can take into account pressure for the zone. The node description file can specify how nodes are connected with each other. In some examples, a weighting can be performed on pressure sensor inputs. The weighted inputs can then be processed in the node. In this example, a minimum function can be beneficial to help determine an area with a lower amount of air flowing through in a particular area or zone.

Another node can take the temperature output and pressure output for the zone and process them together to determine a fan rate for a fan or set of fans. The thermal function can take other things into account, such as thermal properties of a blade, components, heat sinks, etc.

In another example, the fan rate from a node can be used as an input to another node. This other node may also have a fan speed request from a BMC as an input. In one example, the BMC may ask for a pulse width modulation (PWM) value for a fan as part of the input used. In some examples, the fan speed request may be weighted and combined with fan speed requests from other BMCs and/or a weighted fan speed output from another node. In one example, a function can be performed on the fan speed inputs to determine an output to a particular fan, a zone of fans, etc. The function can be a max function, where the speed for the fan(s) may be higher than what is requested by a BMC because of other considerations (e.g., from other nodes).

In some examples, a zone can be a portion of the computing device. The zone can be a particular volume or otherwise determined. In some examples, a set of fans or a zone of fans can be responsible for cooling that zone. The zone can include a number of sensors associated with that zone. In some examples, sensors in adjacent zones can be used as inputs to nodes. Further nodes with sensors in one zone may have an output to another node responsible for an adjacent or another node. Moreover, in some examples, some node outputs can feed back as inputs for nodes that later lead to an input for that node.

At 306, control instructions 426 can be executed by the processing element 410 to control one of the fans according to an output of one of the nodes. This can be based on a transfer function as described herein.

In some examples, the location file and/or node description file can be updated. In one example, the file is updated to support additional sensor inputs. A node description file may add additional nodes, refine nodes, etc. A location file can add additional potential inputs and their possible locations.

The files can be updated on the computing device by interacting with the CMC 400. In one example, the CMC 400 can expose a network interface and a web server to allow a user or other entity (e.g., via an API) to interact with it. The CMC 400 can take update files. In some examples, the particular file can be updated while the computing device is active. A process or function that uses the particular file can be restarted by the CMC 400 to enable usage of the updated file.

Updating the files in this manner allows a developer to quickly test possible configurations of a machine prior to shipment. This allows a test engineer a quick capability to update the configurations and test the configurations.

FIG. 5 is a diagram of a neural network that can be used to control a fan, according to an example. The neural network 501 includes a thermal grid that takes as inputs values provided from various sensors such as sensors 500a-500n, CPLD sensor 504, Power sensor 506, as well as requests from a BMC 502 of a blade or information provided from the BMC 502. Examples of sensors include stand-alone chassis sensors, sensors on various components such as the CPLD sensor 504, power supply sensors 506, sensors at various blades in the system, etc.

As noted above, the sensors can be defined in a location file. The location file can include information needed to access the sensors (e.g., temperature, pressure, current, power, voltage, etc. sensors). In some examples, the location file can be implemented as a human-readable text to transmit object information, for example as a JAVASCRIPT Object Notation (JSON) file, a text file, etc. In some examples, the location file can be considered a sensor description record (SDR).

In one example, the location file can include a part number, a number identifier, a type field, and an address field. The part number can identify a part uniquely (e.g., serial number). The type field can associate a particular sensor or sensor type or other input with a type. The type can be associated with criteria for that type, for example, a weight for a raw number output by that type. The number identifier can be used to identify which number the input is. This can be used to distinguish between different sensors on a table. Moreover, the address field can be used to indicate how the chassis management controller can communicate (e.g., poll) with the input.

In another example, the neural network 501 is implemented as a grid in a node description file. The node description file can also be a human-readable text file. In some examples, the grid can be defined node by node. Nodes can be defined by their inputs, their weights for their inputs, various optional operations performed on data, etc. The nodes can also support optional debug reports to help facilitate grid development.

An input module can take the location file and create an image of the sensors and inputs. It module can then regularly polls those sensors/inputs and store the up-to-date data in an input table.

The neural network creates its grid from the data located in the node description file. In response to a fan module for fan control 530 calling a function to get fan control information (e.g., a “get_fans( )” function), the grid can compute the latest fan data. Such a function can retrieve information to set one fan, a set of fans, a zone of fans, etc. Then the fans can be controlled to respective values.

In one example, an input module updates its input table. This action can be done independently from the fan module. The fan module for fan control 530 calls the grid via the “get_fans( )” function. In one example, the “get_fans( )” creates the neural network from the grid file the first time “get_fans( )” is called.

The “get_fans( )” function can obtain the latest input table from the input module. In one example, “get_fans( )” is only interested in the temperature sensors. In another example, the “get_fans( )” function may also be interested in other sensors, such as pressure sensors, humidity sensors, etc.

Nodes 510a-510m can be used to implement the process for computing each node in the grid. Each input value can be loaded into the grid's source table under the name “inputx” where ‘x’ is the number assigned to the sensor in the location file. Though only one hidden layer is shown, multiple hidden layers can be used. Further, multiple outputs 520 can be implemented. For example, one output can go to one fan control mechanism to control one fan or set of fans while another output goes to another fan control. The grid of nodes computes each node (specified by the node description file).

FIG. 6 is a diagram of a node of a neural network that can be used to provide an output to be used to control a fan, according to one example. The process for computing each node can include loop through all of the node's inputs. The specified weighting to each input can be applied. The weighting can be any percentage number from 0 through +∞ and even negative numbers. A weighting of 100 is 100% in this example.

In one example, an input function 610, such as a maximum function is performed on all of the inputs. In this example, the highest weighted input value is passed on. In the case of thermal values from sensors, the maximum function can be used because it may be considered the most meaningful (the most in need of cooling). In other examples, pressure, humidity, etc. can be taken into account in different function types.

An output function 620 can be applied to the output from the input function 610. In one example, the output function 620 is a running average. This can be controlled by a ‘hysteresis’ field.

In one example, a “maxin” field can be specified for weighted inputs. As such, the inputs can be limited to a particular maximum input at the input function 610 or otherwise along the process. In other examples, a maxin can be set to the input for the output function 620. This can be set in the node description file.

As noted, the output function can be applied. The output function 620 can be implemented as a transfer function in some cases (e.g., when the node's output is to go to a fan control). This can be specified using particular parameters in the node description file. For example, using a proportional, integral, derivative (pids) algorithm, a pids field can be used for parameters. In another example, a ramp function can be used to slowly ramp up fan speeds to keep fans from dealing with current spikes.

The output function 620 can also use a maxout function that is set from the node description file similar to the way that maxin values can be set. When a node completes its processing, the node results are entered into the source table by the name of the node.

When each of the relevant the nodes have been computed, all nodes that are associated with outputs can be put into a dictionary. This is the value returned by the ‘get_fans( )’ function. Fans can be identified by a flag or output designation. In some examples, if a problem occurs, the function will return {“fanmax”:x} as the default. (x would be the default value for a max fan control).

In one example, the node description file can include various information. In this example, each node can be identified by a name. The name that the node is stored under in a source store. In some examples, the source store can include potential sources of information, for example, an input table including sensor information, node outputs, etc. The inputs can be stored there or accessed via the store.

In another example, the node description file can include information about the node's inputs. The node's inputs can define how nodes interact with each other as well as sensors. A list of the inputs can be in the form of a list of lists. In one example, the input is made up of a list with the following fields:

The name of the input. This is used to pull a value from a source store. Sensors inputs can take the form of ‘sensor’ where ‘*’ is the number assigned to sensor in the location file.

The weight. 50 is 50%. 100 is 100%. 250 is 250%. Etc.

In some examples, a MAXIN can be set for the input. After the input has been retrieved from the source store and the weight applied to it; if it exceeds MAXIN, MAXIN is the value that will be passed on. Similarly, a MININ may be used.

In one example, the values of the inputs (after weighting and MAXIN have been applied) can be run through a function such as a MAX function where the largest value is passed on. If there are no valid inputs, the current value is set to a default (e.g., 0 or a MIN).

In another example, a node can have an “offset”, which, if present is a value that is added to the input value.

In a further example, a node “hysteresis” value, which, if present, will trigger a running average using the current value as the latest element. The ‘hysteresis’ value specifies the number of elements used in the running average. For example, a {“hysteresis”: 3} entry would generate a running average with three elements.

In another example, a “maxin” can be a value, that if present, the current value is now limited the ‘maxin’ value.

In another example, a ramp can be defined. If a ramp is defined, this field defines a segmented ramp transfer function if present. It includes a list of lists which defines the kneepoints of a segmented ramp. Each kneepoint is defined by two values (both ints): The first value is compared the current value. A kneepoint will be ignored if the current value is below this first value. The second value defines the output of that kneepoint.

The output is computed as follows: If the current value is <= the first kneepoint, the output will be the output of that kneepoint. If the current value is >= the last kneepoint, the output will be the output of that kneepoint. If the current value is between two kneepoints, the output will be an extrapolation of the outputs of the two kneepoints.

In another example, a “pids” can be defined. It includes a list of four values (floats): The list is the ‘P’ value, an ‘I’ value, a ‘D’ value, and a ‘setpoint’ value. In one example, only one transfer function can be active at a time for a particular node (ramp or pids). Further, max or min outs can be defined.

While certain implementations have been shown and described above, various changes in form and details may be made. For example, some features that have been described in relation to one implementation and/or process can be related to other implementations. In other words, processes, features, components, and/or properties described in relation to one implementation can be useful in other implementations. Furthermore, it should be appreciated that the systems and methods described herein can include various combinations and/or sub-combinations of the components and/or features of the different implementations described. Thus, features described with reference to one or more implementations can be combined with other implementations described herein.

What is claimed is:

1. A computing device comprising:
a chassis including a plurality of fans;
a plurality of blade slots;
a chassis management controller (CMC) to:
implement a neural network including a plurality of nodes,
wherein a first one of the nodes includes a plurality of inputs including: a sensor input and a baseboard management controller (BMC) input from a BMC of a blade coupled to one of the blade slots,
wherein each of the inputs is weighted; and
determine an output for the first one of the nodes based on the inputs, wherein the output is used to control a first one of the fans.

2. The computing device of claim 1, further comprising:
a location file to indicate to the CMC where each of the inputs location is for the first one of the nodes.

3. The computing device of claim 2, further comprising:
a second node of the nodes that includes a second plurality of inputs including a plurality of sensor inputs from a second blade coupled to a second one of the blade slots.

4. The computing device of claim 3, wherein a node description file is to be updated to support the sensor inputs from the second blade.

5. The computing device of claim 4, wherein a function implemented on the CMC is restarted without a restart of the CMC to implement update of the node description file.

6. The computing device of claim 3, wherein the first one of the nodes further includes an input which is an output from a third one of the nodes.

7. The computing device of claim 1, wherein a transfer function is used to determine the output for the first one of the nodes.

8. The computing device of claim 1, wherein the BMC input includes a pulse width modulation (PWM) value.

9. The computing device of claim 8, wherein the BMC controls the BMC PWM value based on a plurality of sensors of the blade.

10. A method comprising:
receiving, at a chassis management controller (CMC) of a computing system including a chassis that includes a plurality of fans, a plurality of blade slots, a plurality of neural network node inputs,
wherein a first one of the neural network inputs includes a baseboard management controller (BMC) input from a BMC of a blade coupled to a first one of the blade slots,
wherein a second one of the neural network inputs includes a sensor input,
wherein each of the neural network inputs is weighted,
determining an output for a first one of the nodes based on the first one and second one of the neural network inputs; and
controlling a first one of the fans according to the output.

11. The method of claim 10, further comprising:
reading, by the CMC a location file; and
determining a location and set of parameters for the first one neural network input and the second one neural network input based on the location file.

12. The method of claim 11, wherein a second node of the nodes that includes a second plurality of inputs including a plurality of sensor inputs from a second blade coupled to a second one of the blade slots.

13. The method of claim 12, further comprising:
updating a node description file to an updated node description file to support the plurality of sensor inputs from the second blade.

14. The method of claim 13, further comprising:
restarting, by the CMC, a function without restarting the CMC to implement usage of the updated node description file.

15. The method of claim 12, wherein the first one of the nodes further includes an input what is an output from a third one of the nodes.

16. The method of claim 10, further comprising:
determining the output for the first one of the nodes using a transfer function.

17. The method of claim 10, wherein the BMC input includes a pulse width modulation (PWM) value, the method further comprising:
controlling, by the BMC, the BMC PWM value based on a plurality of sensors of the blade and a processor usage information.

18. A non-transitory machine-readable storage medium storing instructions that, if executed by a physical processing element of a chassis management controller (CMC) of a device, cause the CMC to:
receive, a plurality of neural network node inputs,
wherein the device includes a chassis that includes a plurality of fans and a plurality of blade slots,
wherein a first one of the neural network inputs includes a baseboard management controller (BMC) input from a BMC of a blade coupled to a first one of the blade slots,
wherein a second one of the neural network inputs includes a sensor input, wherein each of the neural network inputs is weighted,
determine an output for a first one of the nodes based on the first one and second one of the neural network inputs; and
control a first one of the fans according to the output.

19. The non-transitory machine-readable storage medium of claim 18, wherein the BMC input includes a pulse width modulation (PWM) value that is based on a plurality of sensors of the blade and a processor usage information, wherein the output for the first one of the nodes is based on a transfer function.

20. The non-transitory machine-readable storage medium of claim 18, further comprising instructions, that when executed by the physical processing element of the CMC, cause the CMC to:
read a location file;
determine a location and set of parameters for the first one neural network input and the second one neural network input based on the location file.
